(19) United States
(12) Patent Application Publication
(10) Pub. No.: US 2004/0022038 A1
(43) Pub. Date: Feb. 5, 2004

(54) Electronic package with back side, cavity mounted capacitors and method of fabrication therefor

(75) Inventors: David G. Figueroa, Mesa, AZ (US); Chris Baldwin, Chandler, AZ (US); Yuan-Liang Li, Chandler, AZ (US)

Correspondence Address: SCHWEGMAN, LUNDBERG, WOESSNER & KLUTH, P.A., P.O. BOX 2938, MINNEAPOLIS, MN, 55402, US

(73) Assignee: Intel Corporation

(21) Appl. No.: 10/210,391

(22) Filed: Jul. 31, 2002

(51) Int. Cl. H05K 7/06; H01L 23/58

(52) U.S. Cl. 361/763; 361/761; 257/724

(57) ABSTRACT

An electronic package, such as an integrated circuit package, includes a cavity (310, 410 FIGS. 3, 4) on the back side of the package, which is the same side on which connectors (304, 408, FIGS. 3, 4) to a next level of interconnect are located. Within the cavity are contacts (312, 412, FIGS. 3, 4), which enable one or more discrete capacitors (302, 402, FIGS. 3, 4) to be electrically connected to the package. The package provides a very low vertical inductance path between the capacitors and an integrated circuit (314, FIG. 3) mounted on the front side of the package.

### TECHNICAL FIELD OF THE INVENTION

The present invention relates generally to apparatus for providing capacitance to an electronic circuit, and more particularly to an integrated circuit package that includes discrete capacitors and methods of fabrication therefor.

### BACKGROUND OF THE INVENTION

Electronic circuits, and particularly computer and instrumentation circuits, have in recent years become increasingly powerful and fast. As circuit frequencies continue to escalate, with their associated high frequency transients, noise in the power and ground lines increasingly becomes a problem. This noise can arise due to inductive and capacitive parasitics, for example, as is well known. To reduce such noise, capacitors known as bypassing capacitors are often used to provide a stable signal or stable supply of power to the circuitry. Capacitors can also be used to suppress unwanted radiation, to dampen voltage overshoot when an electronic device (e.g., a processor) is powered down, and to dampen voltage droop when the device powers up. Typically, multiple bypassing capacitors are used to provide the desired capacitance.

Bypassing capacitors are generally placed as close as practical to a die load or “hot spot” in order to increase the capacitors' effectiveness. Often, the bypassing capacitors are surface mounted to the die side or land side of the package upon which the die is mounted or embedded within the package itself. FIG. 1 illustrates a cross-section of an integrated circuit package 102 having land side capacitors 104 (“LSC”), and embedded chip capacitors 106 (“ECC”), in accordance with the prior art. LSCs 104 are mounted on the opposite side of the package 102 as the die 108, and ECCs 106 are embedded within the package 102.

The capacitors' terminals (not shown) are connected to integrated circuit loads through electrically conductive vias and patterned planes within package 102, thus enabling the capacitors 104, 106 to provide bypassing capacitance to the integrated circuit 108. Connection of the capacitors to the load through the vias and planes results in some “vertical” inductance, also referred to as “loop” inductance, in the supply and return via loop between each capacitor and the integrated circuit load.

FIG. 2 illustrates an electrical circuit that simulates the electrical characteristics of the capacitors illustrated in FIG. 1. For simplicity, no parasitic resistances of the capacitors or lateral inductances between capacitors are shown in FIG. 2. The circuit shows a die load 202, which may require bypassing capacitance in order to function properly. Some of the bypassing capacitance can be supplied by capacitance, modeled by capacitor 204, located on the die. Other capacitance, however, must be provided off chip, as modeled by off-chip capacitors 206, 208. The off-chip capacitors 206, 208 could be, for example, LSCs 104 and/or ECCs 106, as illustrated in FIG. 1.

As described previously, vertical loop inductance, partially modeled by inductor 210, exists between capacitors 206, 208 and die load 202. For simplicity, a vertical loop inductance component for each capacitor is not shown. Because vertical inductances tend to slow the response time of off-chip capacitors 206, 208, it is desirable to minimize the magnitude of this inductance. Vertical loop inductance can be reduced by placing the off-chip capacitors as electrically close as possible to the die load, such as by using ECCs 106, which typically can be placed closer to the load than surface mounted capacitors.

One disadvantage to using ECCs, however, is that once they are embedded within the package, they are not removable. This can result in lower manufacturing yields, because an entire assembly (i.e., package, integrated circuit, and capacitors) may be rejected if the ECCs are faulty or fail to provide the amount of needed capacitance. In addition, because the ECCs are encapsulated, they tend to retain more heat than surface mounted capacitors, which degrades the amount of charge that the ECCs can hold.

A disadvantage to LSCs is that they cannot be used in conjunction with surface mounted components. Surface mounted components (e.g., CPUs and chipsets) typically have pads, rather than pins, on the bottom side of the component. The pads are connected directly to corresponding pads on a lower level of interconnect (e.g., a printed circuit board). Because of the direct connection, there is no room for LSCs, which would interfere with the ability to surface mount the components. Accordingly, surface mounted components typically must resort to using capacitance solutions (e.g., die side capacitors) with higher inductance characteristics.

Accordingly, there is a need in the art for alternative capacitance solutions, which can provide sufficient capacitance with minimal vertical inductance in the design and fabrication of integrated circuit packages. In addition, what is needed is a low-inductance capacitance solution that enables discrete capacitors to be removed and replaced, if necessary. Further needed is a capacitance solution in which discrete capacitors are less susceptible than ECCs to performance degradation from heat produced by the capacitors. Further needed is a capacitance solution that has low inductance characteristics and can be used in conjunction with surface mounted components.

### BRIEF DESCRIPTION OF THE DRAWING

FIG. 1 illustrates a cross-sectional, side view of an integrated circuit package having land side and embedded chip capacitors, in accordance with the prior art;

FIG. 2 illustrates an electrical circuit that simulates the electrical characteristics of the capacitors illustrated in FIG. 1;

FIG. 3 illustrates a cross-sectional, side view of an integrated circuit package having back side capacitors, in accordance with one embodiment of the present invention;

FIG. 4 illustrates a cross-sectional, side view of an integrated circuit package having back side capacitors, in accordance with another embodiment of the present invention;

FIG. 5 illustrates a bottom view of an integrated circuit package having back side capacitors, in accordance with one embodiment of the present invention;

FIG. 6 illustrates a flowchart of a method for manufacturing an integrated circuit package having back side capacitors, in accordance with one embodiment of the present invention;

FIG. 7 illustrates an integrated circuit package, socket, and printed circuit board, in accordance with one embodiment of the present invention; and

FIG. 8 illustrates an electronic system, in accordance with one embodiment of the present invention.

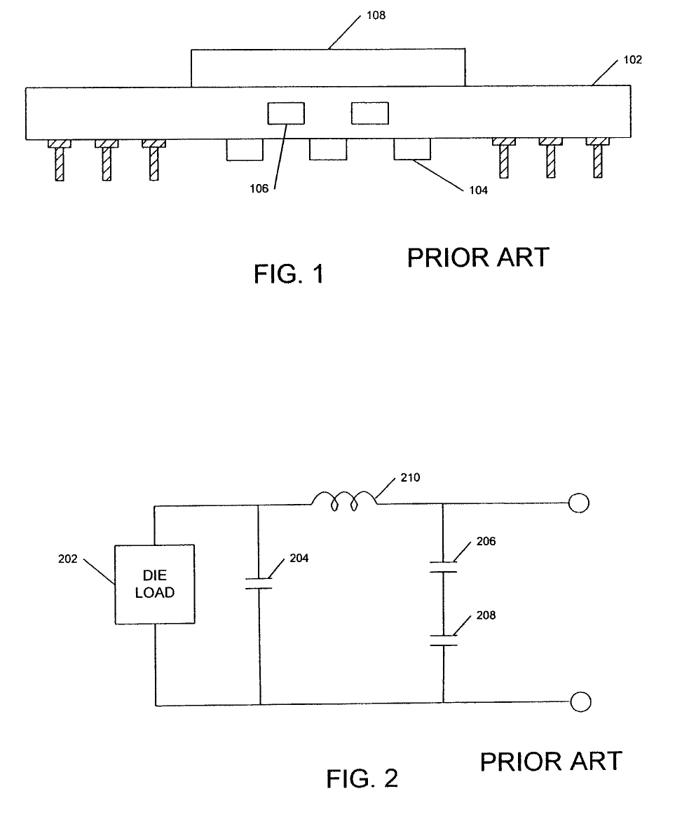

### DETAILED DESCRIPTION OF THE INVENTION

Various embodiments of the present invention provide off-chip capacitance at low vertical inductance levels for bypassing, voltage dampening, and supplying charge. In addition, the capacitors of the various embodiments are removable, and retain less heat than ECCs. In various embodiments, this is accomplished by mounting discrete capacitors within a cavity formed on the land-side of a package. To distinguish these cavity mounted capacitors from LSCs, the capacitors used in conjunction with the various embodiments are referred to herein as “back side capacitors” or “BSCs.” The term “back side” is meant to indicate the side of a package on which connectors to a next level of interconnect (e.g., a socket, interposer or PC board) are present. This is distinguishable from the “front side,” which is meant to indicate the side of a package on which an integrated circuit chip is mounted.

Although the description of the various embodiments refers primarily to using discrete capacitors in conjunction with an integrated circuit package, the various embodiments also could be used in conjunction with other types of packages, interposers, printed circuit (PC) boards or other electronic circuit housings. In other words, the various embodiments could be used in conjunction with various types of electronic assemblies, and is not meant to be limited to use with integrated circuit packages. In addition, the various embodiments could be used with a number of different types of packages and packaging technologies. For example, the various embodiments could be used with organic or ceramic packages, and the packaging technologies with which the embodiments could be used include but are not limited to, land grid array (e.g., organic LGA), pin grid array (e.g., plastic PGA or flip chip PGA), ball grid array (e.g., μBGA, tape BGA, plastic BGA, flip chip BGA or flip chip tape BGA), and beam lead.

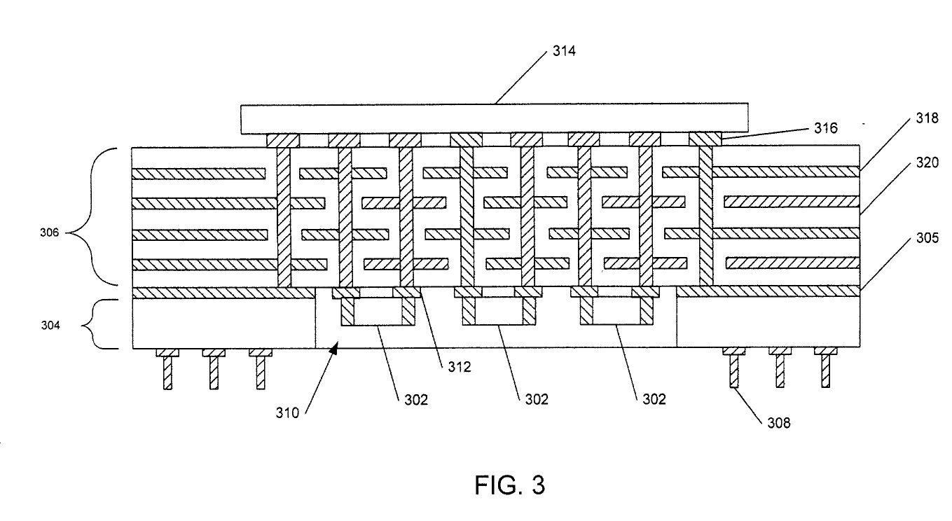

FIG. 3 illustrates a cross-sectional, side view of an integrated circuit package having BSCs 302, in accordance with one embodiment of the present invention. The package includes a core layer 304 and a set of package layers 306 formed above the top surface of the core layer 304.

Core layer 304 is formed from a rigid substrate material. In an organic package, the substrate material could be a standard PC board material. In an inorganic package, the substrate material could be a layer of ceramic, for example. In one embodiment, the thickness of core layer 304 is in a range of about 500-1000 microns, although core layer 304 could be thicker or thinner, in other embodiments.

Conductive structures (not shown) within core layer 304 provide electrical connections between conductive structures within the set of package layers 306 and connectors 308 on the bottom surface of the package. These conductive structures could include, for example, vias, trenches or other vertical connections. Connectors 308 could be conductive pins, as illustrated or they could be conductive pads. Connectors 308 enable the package to be attached to a socket, interposer or PC board.

The set of package layers 306 includes one or more layers of patterned conductive material 318 separated by one or more layers of dielectric material 320. The dielectric layers 320 could be formed from organic or inorganic materials. Conductive layers 318 could be formed from copper, although other conductive materials could be used in other embodiments. In one embodiment, the thickness of conductive layers 318 is in a range of about 10-20 microns, and the thickness of dielectric layers 320 is in a range of about 25-35 microns, although layers 318, 320 could be thicker or thinner, in other embodiments. Conductive layers 318 are electrically interconnected through conductive structures (not shown), which could include vias, trenches or other vertical connections.

In one embodiment, a conductive layer 305 is formed on the top surface of core layer 304, and thus exists between core layer 304 and package layers 306. For descriptive purposes, this layer will be referred to herein as the “first front side conductive layer.”

A set of conductive pads 316 are formed on the top surface of the set of package layers 306. In one embodiment, an integrated circuit chip 314 is attached to these pads 316. Accordingly, pads 316 provide electrical connections between the integrated circuit 314 and conductive structures (e.g., planes, vias, etc.) within the set of package layers 306.

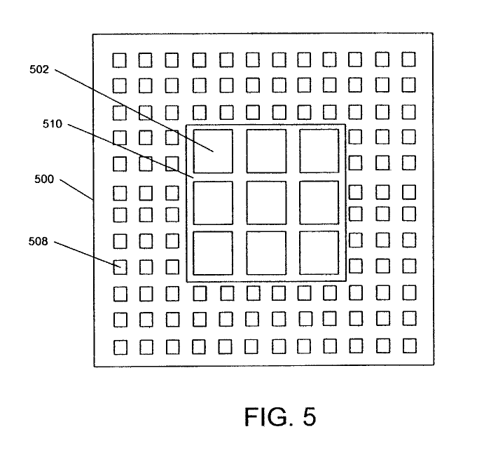

A cavity 310 is formed through a center region of core layer 304, extending through the bottom and top surfaces of core layer 304. The center region is a region of the core layer 304 that is substantially underneath an integrated circuit 314 attached to the front side of the package. For packages where connectors 308 exist around the periphery of the bottom of the package (see FIG. 5, for example), the center region is the region of the package within but not intersecting the area that the connectors occupy. In one embodiment, cavity 310 does not extend into the set of package layers 306, although cavity 310 could extend through one or more of these layers, in alternate embodiments. In one embodiment, the depth of cavity 310 is such that when discrete capacitors 302 are mounted within cavity, the discrete capacitors are fully contained within cavity 310 and do not extend outside cavity 310 (i.e., the depth of cavity 310 is greater than or equal to the height of discrete capacitor 302). In an alternate embodiment, a portion of the discrete capacitors 302 could extend outside cavity 310.

Conductive contacts or pads 312 are formed within cavity 310. These pads 312 are formed on the upper boundary of cavity 310, which in one embodiment, is the bottom surface of the set of package layers 306. The pads 312 represent portions of the first front side conductive layer 305, having been selectively retained in an etching process, in one embodiment. In another embodiment, the pads 312 could be selectively applied to the upper boundary of cavity 310. In still other embodiments, where the cavity 310 extends through one or more of the package layers 306, the pads 312 would be formed on the bottom of the lowest package layer 306 through which the cavity 310 does not extend.

One or more discrete, BSCs 302 are attached to these pads 312. Accordingly, pads 312 provide electrical connections between the BSCs 302 and conductive structures within the set of package layers 306. Ultimately, these conductive structures enable capacitance to be supplied to integrated circuit 314 mounted on the package.

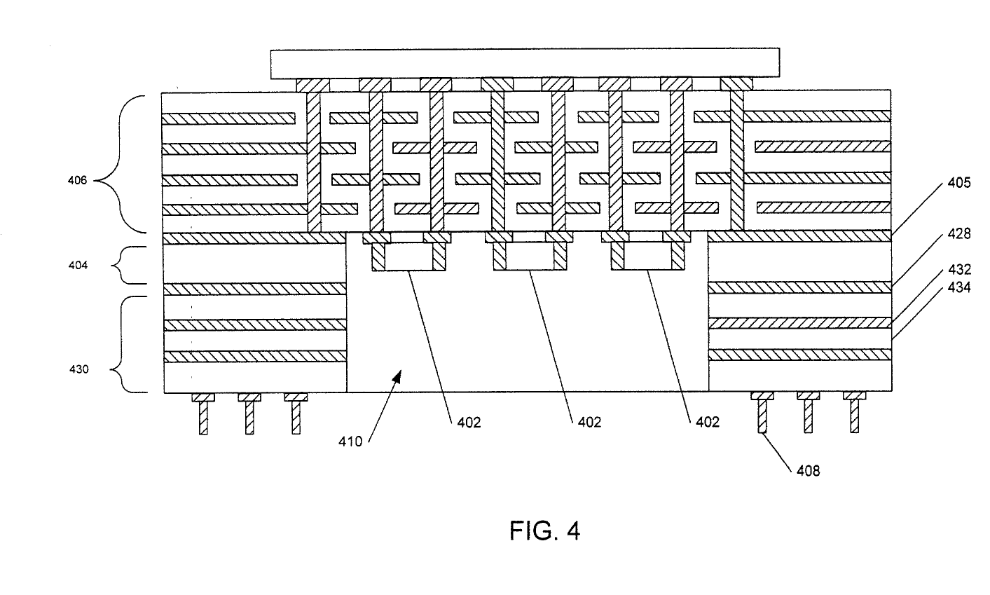

FIG. 4 illustrates a cross-sectional, side view of an integrated circuit package having BSCs 402, in accordance with another embodiment of the present invention. The embodiment illustrated in FIG. 4 is similar to the embodiment illustrated in FIG. 3, except that in the embodiment illustrated in FIG. 4, the package includes a second set of package layers 430 formed below the bottom surface of the core layer 404. For purposes of description, second set of package layers 430 will be referred to herein as “back side layers,” and the first set of package layers 406 will be referred to herein as “front side layers.”

The second set of package layers 430 includes one or more layers of patterned conductive material 432 separated by one or more layers of dielectric material 434. Materials and dimensions relating to the package layers were described previously in conjunction with the first set of package layers 306 (FIG. 3), and these materials and dimensions apply as well to the second set of package layers 430.

Conductive layers 432 are electrically interconnected together, to core layer 404, and to bottom connectors 408 through conductive structures (not shown), which could include vias, trenches or other vertical connections. Bottom connectors 408 could be conductive pins or pads, in various embodiments.

In one embodiment, a first front side conductive layer 405 is formed on the top surface of core layer 404, and thus exists between core layer 404 and the first set of package layers 406. In addition, in one embodiment, a conductive layer 428 is formed on the bottom surface of core layer 404, and thus exists between core layer 404 and the second set of package layers 430. For descriptive purposes, this layer will be referred to herein as the “first back side conductive layer.”

Cavity 410 is formed through a center region of core layer 404 and back side layers 430, extending through the bottom and top surfaces of core layer 404 and layers 430. In one embodiment, cavity 410 does not extend into front side layers 406, although cavity 410 could extend through one or more of these layers, in alternate embodiments.

For ease of illustration, FIGS. 3 and 4 do not completely illustrate all of the various conducting and non-conducting layers that a package may have. Layers above and/or below layers 306, 406, 430 may also exist. In addition, although only three discrete capacitors 302, 402 are shown, more or fewer capacitors can be attached within cavities 310, 410. Also, more or fewer pads 312, 316 and/or connectors 308, 408 could be used in other package configurations.

FIG. 5 illustrates a bottom view of an integrated circuit package 500 having BSCs 502, in accordance with one embodiment of the present invention. As described above, capacitors 502 are attached to package 500 within a cavity 510 formed through a center region of the bottom of package 500.

In the illustrated configuration, bottom connectors 508 are located around the periphery of cavity 510, enabling the package 500 to be attached to a socket, interposer or PC board. As described previously, connectors 508 could be pins or pads, depending on the packaging technology used.

For ease of illustration, only nine discrete capacitors 502 are shown in FIG. 5. In alternate embodiments, more or fewer capacitors can be attached within cavity 510. Also, more or fewer connectors 508 could be used in other package configurations.

In various embodiments, each capacitor 302, 402, 502 illustrated in FIGS. 3-5 could be a ceramic capacitor, aluminum oxide capacitor, organic capacitor or a capacitor made with many other technologies, as would be obvious to one of skill in the art based on the description herein. These capacitors could have from two to many external terminals distributed on two or four sides. In addition, the actual and relative dimensions of the packages, integrated circuits, and discrete capacitors could vary widely, depending on design and manufacturing constraints or other factors.

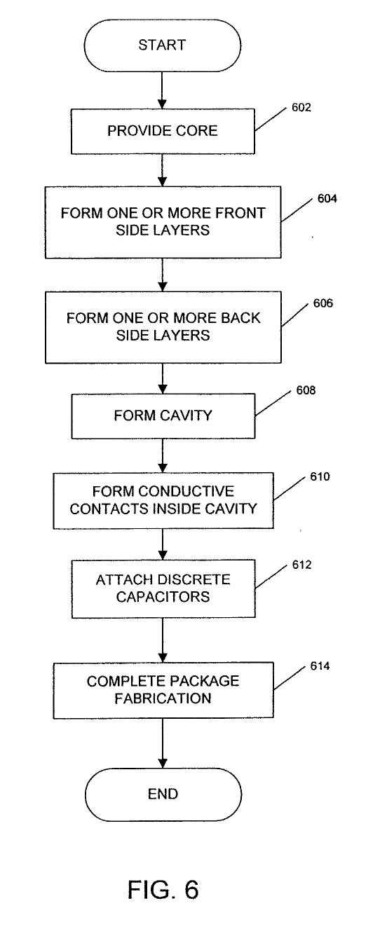

FIG. 6 illustrates a flowchart of a method for manufacturing an integrated circuit package having BSCs, in accordance with one embodiment of the present invention. The method begins, in block 602, by providing a core layer (e.g., layer 304). In one embodiment, core layer is formed of a rigid, dielectric material, and may or may not include conductive layers on its top and/or bottom surfaces. For example, the core layer could be formed from organic PC board materials, such as an epoxy material, in one embodiment. For example, standard PC board materials such as FR-4 epoxy-glass, polymide-glass, benzocyclobutene, Teflon, other epoxy resins, injection molded plastic or the like could be used in various embodiments. In alternate embodiments, the substrate could consist of inorganic PC board materials, such as ceramic, for example.

Vias and/or other vertical connections are formed in the core layer, enabling electrical connections to be made between the top and bottom surfaces of the core layer. Formation of conventional vias or other vertical connections can be performed using techniques well known to those of skill in the art. In one embodiment, vias are laser or mechanically drilled and plated or filled with a conductive material, although vias may also be punched or formed using other techniques in various embodiments.

Next, in block 604, a set of one or more front side package layers (e.g., layers 306, 406, FIGS. 3, 4) and interconnections are formed above the top surface (i.e., the front side) of the core layer. As described previously, these layers alternate between conducting and non-conducting materials. The conductive layers can be patterned during the build-up process, and vias and/or other vertical connections can be formed during the build-up process, as well.

The set of front side package layers and interconnections are formed using standard build-up techniques, which are well known to those of skill in the art. For organic packages, these techniques can include, for example, any combination of photolithography, material deposition, plating, drilling, printing, lamination, and other processes for selectively adding or removing conductive and non-conductive materials. For inorganic packages, these techniques can include, for example, pre-forming and stacking ceramic layers and patterned conductive layers.

In one embodiment, the conductive material is copper, although other conductive materials such as tin, lead, nickel, gold, palladium or other materials could be used in other embodiments. The non-conductive material is formed from organic PC board materials, such as an epoxy material, in one embodiment. For example, standard PC board materials such as FR-4 epoxy-glass, polymide-glass, benzocyclobutene, Teflon, other epoxy resins, injection molded plastic or the like could be used in various embodiments. In alternate embodiments, the non-conductive material could consist of inorganic PC board materials, such as ceramic, for example.

In one embodiment, a first front side conductive layer (e.g., layer 305, 405, FIGS. 3, 4) exists between the core layer and the set of front side package layers. This conductive layer could be pre-formed on the core layer or could be formed during the build-up process. In one embodiment, the first front side conductive layer has conductive material over substantially the whole area in which the cavity will eventually be formed. In an alternate embodiment, the layer could be patterned over the area in which the cavity will be formed. In still another embodiment, the first front side conductive layer does not exist.

In one embodiment, a set of one or more back side package layers (e.g., layers 430, FIG. 4) is formed below the bottom surface (i.e., the back side) of the core layer, in block 606. As described previously, these layers alternate between conducting and non-conducting materials. The conductive layers can be patterned during the build-up process, and vias and/or other vertical connections can be pre-formed and/or formed during the build-up process, as well. The set of back side package layers and interconnections are formed using standard build-up processes, described above, which are well known to those of skill in the art.

In one embodiment, a first back side conductive layer (e.g., layer 428, FIG. 4) exists between the core layer and the set of back side package layers. This conductive layer could be pre-formed on the core layer or could be formed during the build-up process. The first back side conductive layer is formed, in one embodiment, so that conductive material does not exist in the area through which the cavity (e.g., cavity 310, 410, FIGS. 3, 4) will extend. In other embodiments, the first back side conductive layer does include conductive material in the area through which the cavity will extend, or the first back side conductive layer may not exist.

Although the above description indicates that front side package layers are formed before back side package layers, the order of layer formation could be opposite or both the front and back side package layers could be formed simultaneously. In another embodiment, the package could include the front side package layers but not the back side package layers.

In block 608, a cavity (e.g., cavity 310, 410, 510, FIGS. 3-5) is formed in a center region of the package. In one embodiment, the cavity is formed using a masking and etching process, as is well known to those of skill in the art. In other embodiments, the cavity could be formed by drilling, punching or mechanically removing the appropriate portions of the core and conductive and non-conductive layers. In still another embodiment, where the package is formed from inorganic materials, the cavity could be created by forming an opening in the center region of the core layer when the core layer is pre-formed and, if the cavity extends though package layers, by forming openings in the package layers, as well.

In one embodiment, the cavity is formed through all back side package layers (e.g., layers 430, FIG. 4) and through the core layer (e.g., layer 304, 404, FIGS. 3, 4), but not through the first front side conductive layer (e.g., layer 305, 428, FIGS. 3, 4) or the other front side conductive layers (e.g., layers 306, 406, FIGS. 3, 4). In alternate embodiments, the cavity could be formed through the first front side conductive layer and/or one or more other front side package layers.

Next, in block 610, conductive contacts (e.g., pads 312, 412, FIGS. 3, 4) are formed inside the cavity. These pads are formed on the upper boundary of the cavity, which in one embodiment, is the bottom surface of the set of front-side package layers. In other embodiments, where the cavity extends through one or more of the front side package layers, the pads would be formed on the bottom of the lowest package layer through which the cavity does not extend.

The conductive contacts could be formed, for example, by selectively removing portions of the first front side conductive layer. Alternatively, the contacts could be formed by selectively applying conductive material inside the cavity. These selective addition or removal processes are well known to those of skill in the art, and were described previously in conjunction with the description of the package layer build-up processes.

In block 612, one or more discrete BSCs (e.g., capacitors 302, 402, 502, FIGS. 3-5) are surface mounted to the conductive contacts formed within the cavity. Attachment can be performed by soldering the cavity connectors and the capacitor terminals together. Alternatively, a cured, conductive paste or adhesive could be used to provide the capacitor-to-pad connections.

Finally, in block 614, the package fabrication is completed. In one embodiment, this includes attaching pins (e.g., pins 308, 408, FIGS. 3, 4) or forming other types of connectors (e.g., pads) on the bottom surface of the package. Also, connectors are formed on the top surface, and an integrated circuit chip (e.g., chip 314, FIG. 3) is attached to the top surface connectors. The integrated circuit can be sealed, if necessary. Finally, other processes necessary to complete package fabrication are performed. Some or all of the processes described in conjunction with block 614 could be performed in parallel with or before the process blocks described previously. The process then ends.

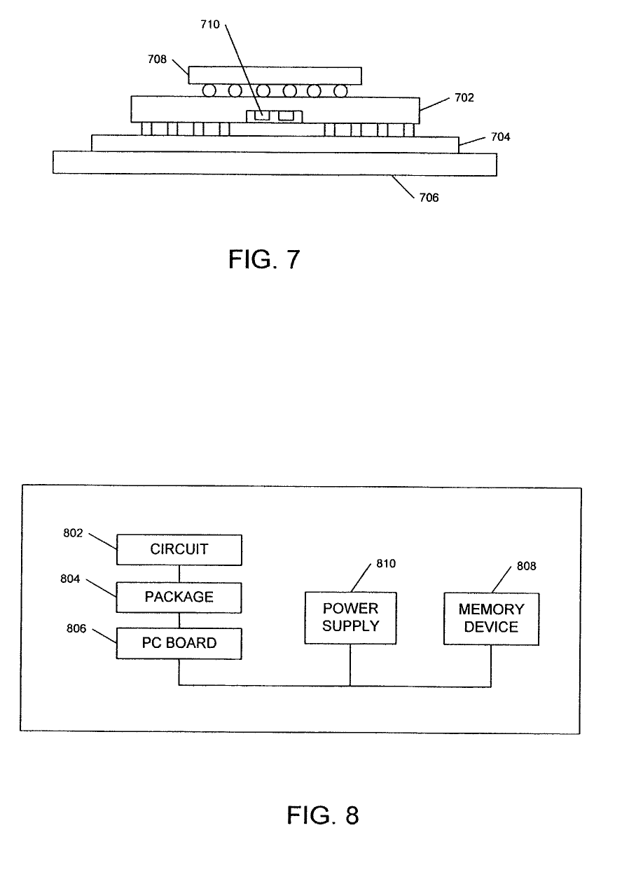

FIG. 7 illustrates an integrated circuit package 702, socket 704, and PC board 706, in accordance with various embodiments of the present invention. Starting from the top of FIG. 7, an integrated circuit 708 is housed by integrated circuit package 702. Integrated circuit 708 contains one or more circuits, which are electrically connected to integrated circuit package 702.

Integrated circuit 708 could be any of a number of types of integrated circuits. In one embodiment of the present invention, integrated circuit 708 is a microprocessor. In other embodiments, integrated circuit 708 could be a memory device, application specific integrated circuit, digital signal processor or another type of device. In the example shown, integrated circuit 708 is a “flip chip” type of integrated circuit, meaning that the input/output terminations on the chip can occur at any point on its surface. After the chip has been readied for attachment to integrated circuit package 702, it is flipped over and attached, via solder bumps or balls to matching pads on the top surface of integrated circuit package 702. Alternatively, integrated circuit 708 could be wire bonded, where input/output terminations are connected to integrated circuit package 702 using bond wires to pads on the top surface of integrated circuit package 702 or otherwise connected to package 702.

One or more of the circuits within integrated circuit 708 acts as a load, which may require bypassing capacitance for noise or radiation suppression, and/or voltage dampening. Some of this capacitance is provided, in one embodiment of the present invention, by BSCs 710 (e.g., capacitors 302, 402, 502, FIGS. 3-5), which are surface mounted within a cavity (e.g., cavity 310, 410, 510, FIGS. 3-5) on the back side of package 702. In this manner, one or more levels of additional capacitance are provided to integrated circuit 708. In other embodiments, BSCs are surface mounted within cavities on an interposer (not shown), socket 704, and/or PC board 706.

Integrated circuit package 702 is coupled to PC board 706 through a socket 704 on PC board 706. In the example shown, package 702 includes pins, which mate with complementary pin holes in socket 704. Alternatively, package 702 could be electrically and physically connected to PC board 706 using solder connections, such as ball grid array connections, for example. In still another alternate embodiment, integrated circuit package 702 could be connected to socket 704 and/or PC board 706 through an interposer (not shown). Other ways of connecting integrated circuit package 702 and PC board 706 could also be used in other embodiments.

PC board 706 could be, for example, a motherboard of a computer or other electronic system. As such, it acts as a vehicle to supply power, ground, and signals to integrated circuit 708. These power, ground, and other signals are supplied through traces or planes (not shown) on or within PC board 706, socket 704, and integrated circuit package 702.

The configurations described above in conjunction with various embodiments could form part of an electronic system. FIG. 8 illustrates an electronic system, in accordance with one embodiment of the present invention. The system shown in FIG. 8 could be, for example, a computer, a wireless or wired communication device (e.g., telephone, modem, cell phone, pager, radio, etc.), a television, a monitor or virtually any other type of electronic system that could benefit from the use of back side, cavity mounted capacitors.

The electronic system includes circuit 802, package 804, PC board 806, memory device 808, and power supply 810. Package 804 and/or PC board 806 include one or more BSCs mounted within a cavity, in accordance with various embodiments of the present invention.

Conclusion

Various embodiments of an integrated circuit package with back side, cavity mounted capacitors and methods of fabricating that package have been described, along with a description of the incorporation of the package within an electronic system. The various embodiments can be used to reduce the vertical inductance present between discrete capacitors and integrated circuit loads. By utilizing back side, cavity mounted capacitors, the various embodiments provide a capacitance solution in which capacitors are replaceable and are less susceptible to heat-related performance degradation. In addition, the various embodiments can be used in conjunction with a surface mounted component having pads on its bottom surface, because the back side, cavity mounted capacitors will not interfere with the connection of those pads to corresponding pads on a next level of interconnect.

While the foregoing examples of dimensions and ranges are considered typical, the various embodiments of the invention are not limited to such dimensions or ranges. It is recognized that the trend within industry is to generally reduce device dimensions for the associated cost and performance benefits.

In the foregoing detailed description, reference is made to the accompanying drawings, which form a part hereof, and in which are shown by way of illustration specific embodiments in which the invention may be practiced. These embodiments are described in sufficient detail to enable those skilled in the art to practice the invention.

It will be appreciated by those of ordinary skill in the art that any arrangement, which is calculated to achieve the same purpose, may be substituted for the specific embodiment shown. The various embodiments have been described in the context of providing excess, off-chip capacitance to a die. One of ordinary skill in the art would understand, based on the description herein, that the method and apparatus of the present invention could also be applied in many other applications where a capacitor configuration having a low vertical inductance, replaceability, and/or improved heat dissipation is desired. Therefore, all such applications are intended to fall within the spirit and scope of the present invention.

This application is intended to cover any adaptations or variations of the present invention. The foregoing detailed description is, therefore, not to be taken in a limiting sense, and it will be readily understood by those skilled in the art that various other changes in the details, materials, and arrangements of the parts and steps, which have been described and illustrated in order to explain the nature of this invention, may be made without departing from the spirit and scope of the invention as expressed in the adjoining claims.

What is claimed is:

1. An integrated circuit package comprising:
a core layer formed from a rigid substrate material and having a top surface, a bottom surface, and a cavity formed through a center region and extending through the top surface and the bottom surface;
a first set of package layers, formed above the top surface of the core layer and over the cavity, which includes one or more layers of patterned conductive material separated by one or more layers of dielectric material;
first conductive pads formed within the cavity, wherein the first conductive pads provide electrical connections between one or more discrete capacitors and the first set of package layers; and
second conductive pads formed on a top surface of the first set of package layers, wherein the second conductive pads provide electrical connections between an integrated circuit attached to the second conductive pads and the first set of package layers.

2. The integrated circuit package as claimed in claim 1, further comprising a first conductive layer formed on the top surface of the core layer, wherein the first conductive pads are portions of the first conductive layer.

3. The integrated circuit package as claimed in claim 1, further comprising a second set of package layers, formed below the bottom surface of the core layer, which includes one or more additional layers of patterned conductive material separated by one or more additional layers of dielectric material.

4. The integrated circuit package as claimed in claim 1, wherein a thickness of the core layer is in a range of about 500 to 1000 microns.

5. The integrated circuit package as claimed in claim 1, further comprising an integrated circuit mounted on and electrically connected to the second conductive pads.

6. The integrated circuit package as claimed in claim 1, further comprising the one or more discrete capacitors electrically connected to the first conductive pads.

7. The integrated circuit package as claimed in claim 1, further comprising multiple connectors on a bottom surface of the integrated circuit package.

8. The integrated circuit package as claimed in claim 1, wherein the one or more layers of dielectric material are formed from organic materials.

9. The integrated circuit package as claimed in claim 1, wherein the one or more layers of dielectric material are formed from ceramic.

10. An electronic system comprising:
an integrated circuit package having
a core layer formed from a rigid substrate material and having a top surface, a bottom surface, and a cavity formed through a center region and extending through the top surface and the bottom surface,
a first set of package layers, formed above the top surface of the core layer and over the cavity, which includes one or more layers of patterned conductive material separated by one or more layers of dielectric material,
first conductive pads formed within the cavity, wherein the first conductive pads provide electrical connections between one or more discrete capacitors and the first set of package layers, and
second conductive pads formed on a top surface of the first set of package layers, wherein the second conductive pads provide electrical connections between an integrated circuit attached to the second conductive pads and the first set of package layers;
the one or more discrete capacitors electrically connected to the first conductive pads; and
the integrated circuit attached to the second conductive pads.

11. The electronic system as claimed in claim 10, wherein the one or more discrete capacitors are ceramic capacitors.

12. The electronic system as claimed in claim 10, further comprising multiple connectors on a bottom surface of the integrated circuit package.

13. The electronic system as claimed in claim 12, wherein the multiple connectors are conductive pins.

14. The electronic system as claimed in claim 12, wherein the multiple connectors are conductive pads.

15. The electronic system as claimed in claim 10, wherein the integrated circuit is a microprocessor.

16. The electronic system as claimed in claim 10, further comprising:
a power supply; and
a memory device.

17. A method for manufacturing an integrated circuit package, the method comprising:
providing a core layer formed of a rigid dielectric material;
forming one or more front side layers above a top surface of the core layer, wherein the one or more front side layers alternate between conducting layers and non-conducting layers, and an integrated circuit is mountable on a top surface of the one or more front side layers;
forming a cavity through a center region of the core layer and extending through the top surface and a bottom surface of the core layer; and
forming conductive pads within the cavity, wherein the conductive pads provide electrical connections between one or more discrete capacitors and the one or more front side layers.

18. The method as claimed in claim 17, further comprising attaching the one or more discrete capacitors to the conductive pads by surface mounting the one or more discrete capacitors to the conductive pads.

19. The method as claimed in claim 17, further comprising forming one or more back side layers below a bottom surface of the core layer, wherein the one or more back side layers alternate between conducting layers and non-conducting layers, the cavity extends through the one or more back side layers, and conductive connectors are attachable to a bottom surface of the one or more back side layers.

20. The method as claimed in claim 19, further comprising attaching conductive pins to the bottom surface of the one or more back side layers, wherein the conductive pins are the conductive connectors.

21. The method as claimed in claim 17, wherein the core is formed from an organic material, and forming the one or more front side layers comprises using build-up techniques that include photolithography, material deposition, plating, and drilling.

22. The method as claimed in claim 21, wherein forming the cavity comprises using a masking and etching process.

23. The method as claimed in claim 17, wherein the core is formed from ceramic, and forming the one or more front side layers comprises pre-forming and stacking ceramic layers and non-conductive layers.

24. The method as claimed in claim 23, wherein forming the cavity comprises pre-forming the core layer with an opening in a center region of the core layer.
